(19) United States
(12) Patent Application Publication
(10) Pub. No.: US 2009/0000811 A1
(43) Pub. Date: Jan. 1, 2009

(54) Chip resistor and method for fabricating the same

(75) Inventor: Rong-Tzer TSAI, Kaohsiung (TW)

Correspondence Address: Muncy, Geissler, Olds & Lowe, PLLC, P.O. BOX 1364, FAIRFAX, VA, 22038-1364, US

(73) Assignee: FEEL CHERNG ENTERPRISE CO., LTD.

(21) Appl. No.: 12/153,157

(22) Filed: May 14, 2008

(30) Foreign Application Priority Data
Jun. 29, 2007 (TW) 096123659

(51) Int. Cl. H05K 1/16; H05K 3/34

(52) U.S. Cl. 174/260; 29/840

(57) ABSTRACT

A chip resistor and method for fabricating the same are disclosed according to the present invention, wherein a thermic welding layer is applied to bond together a substrate and a resistor in face-to-face orientation, and a passivation layer is applied to partially cover the resistor, such that it consequently divides the surface of the resistor into a covered portion and two uncovered portions that serve as electrode zones, thereby eliminating unnecessary current transmission impedance as in prior art, as well as efficiently and stably reducing the temperature coefficient of resistance. The bonding design of the substrate and the resistor of the present invention is capable of overcoming the drawback of the high cost of semiconductor processing as used in the prior art by providing a simple fabrication process that is capable of increasing process yield and decreasing production costs.

### BACKGROUND OF THE INVENTION

1. Field of the Invention

This invention generally relates to a kind of resistor, and more specifically, to a kind of chip resistor that has a low temperature coefficient of resistance and a method for fabricating the same.

2. Description of Related Art

In accordance with the trend towards microminiaturization and the portability of various electronic devices, chip resistors—which are frequently applied in circuits for establishing an electric potential difference between two terminals for measuring purposes—are accordingly trending towards microminiaturization as well. Moreover, in order to reduce measurement error as well as raise the detected current value (in addition to reducing the temperature coefficient of resistance) resistance values of from 0.02Ω to 10Ω capable of high power with a permissible wattage rating over 0.1 W are commonly demanded. However, printing and coating techniques, which are presently the most applied fabrication techniques of the prior arts, have practical disadvantages that hinder mass production at low cost.

A chip resistor has been disclosed according to the claims of R. O. C. Patent No. 350071, wherein a resistant film, which is a resistant adhesive made of a mixture of glass and electro-conductive particles, is printed on a ceramic substrate by means of a screen printing technique, and, subsequently the resistant film is shaped via processes of drying, high sintering, and others. Then, a part of the resistant film is melted down to form a trench for adjusting its resistance through a laser heating/trimming process, and then electrodes are made through an electroplating process. However, the resistant film is formed by means of a printing technique, and it is difficult to control the uniformity of the thickness of the resistant film. Moreover, because of the effect of broadening variance at high sintering, the variance of resistance of the resistant film is high since the resistant film has high porosity and a loose structure. Therefore, resistors formed with such a technique are not suitable for some applications, particularly when the aforementioned chip resistor is applied in a high-frequency environment, wherein such a resistor could easily cause high-frequency signals to significantly degrade.

In another fabrication method that applies a coating technique, a resistant film is formed on a ceramic substrate in a semiconductor fabrication process by means of physical vapor deposition (PVD) or chemical vapor deposition (CVD), such as sputter deposition or evaporation deposition or others. However, in that fabrication of the chip resistor using this technique involves semiconductor fabrication processes, the equipment investment is relatively high, and also the process yield has its limitations. Thus, the production cost is generally quite high, thereby greatly decreasing the competitive edge of such products. Additionally, in the aforementioned semiconductor process, the resistant film is formed in a patterning process via photolithography, wherein a photoresist film has to be removed before proceeding to subsequent processes. However, in the process of removing the photoresist film, the situation of incomplete removal or excessive removal often happens, and, consequently, the resistant film can be left exposed and then get contaminated or oxidized, thereby affecting its electrical properties, and, accordingly, decreasing the process yield.

In order to overcome the aforementioned drawbacks, a fabrication method has been disclosed according to the claims of R. O. C. Patent No. 1237898, wherein two main electrodes are first separately formed on two ends of an insulated substrate. Next, a resistant film is formed on the upper surface of the insulated substrate by means of thin film deposition. Following that, a first passivation layer is formed on the resistant film formed in previous step by means of printing, wherein the first passivation layer covers at least the part of resistant film between the two main electrodes but exposes the resistant film in the two neighborhoods of the two main electrodes. This first passivation layer that covers between the two main electrodes extends continuously, and subsequently the first passivation layer is used as a mask to remove the uncovered resistant film, wherein at last two plane electrodes are formed on the two terminals of the insulated substrate, each separately covering its corresponding main electrode.

However, the foregoing technique still resorts to semiconductor fabrication processing, leaving the problems of high cost and poor yield still unsolved. Also, the coating process for the two extra passivation layers raises costs even more. In addition, the resistant film is indirectly electrically connected to the plane electrodes via the main electrodes, thereby increasing the temperature coefficient of resistance of the resistant film and the main electrodes, and, consequently, the temperature coefficient of resistance of the fabricated chip resistor can often not be reduced to the desired value. Moreover, even the heat dissipation efficiency is undesirably reduced.

In summary, the aforementioned prior art has the drawbacks of low fabrication process yield, unavoidable high equipment and production costs, inability of reducing the temperature coefficient of resistance to the required value, and others. Therefore, it is highly desirable in the industry to find a way to provide a chip resistor and method for fabricating the same that can effectively solve the above drawbacks.

### SUMMARY OF THE INVENTION

In view of the disadvantages of the prior art mentioned above, it is a primary objective of the present invention to provide a chip resistor and method for fabricating the same that have a simple fabrication process and are capable of increasing the fabrication process yield.

It is another objective of the present invention to provide a chip resistor and method for fabricating the same that are capable of stably decreasing the temperature coefficient of resistance to the desired range.

It is a further objective of the present invention to provide a chip resistor and method for fabricating the same that are capable of decreasing production costs.

To achieve the aforementioned and other objectives, a fabrication method for a chip resistor is provided according to the present invention. The fabrication method comprises: providing a substrate and a resistor; bonding the substrate and the resistor together in face-to-face orientation via a thermic welding layer; and partially covering the surface of the resistor with a passivation layer, such that the passivation layer divides the surface of the resistor into a covered portion and two opposed uncovered portions with the covered portion located therebetween, wherein the two uncovered portions serve as electrode zones.

In the aforesaid fabrication method, the thermic welding layer can be at least two alternate solder bumps, wherein there is no restriction on the size or shape of the solder bumps. In one embodiment, a solder material is pre-coated on the surface of the substrate, and then the resistor is placed on the substrate. Then, after being through a thermic welding process, the solder material transforms into the solder bumps that bond the substrate and the resistor together. In another embodiment, a solder material is pre-coated on the surface of the resistor, and then the resistor is placed on the substrate, and after being through a thermic welding process, the solder material transforms into the solder bumps that bond the substrate and the resistor together. The aforesaid solder material has a temperature coefficient of resistance closer to those of the substrate and the resistor, and, preferably, the solder material has better thermo-conductivity. In this method, there are no specified restrictions on the solder material; it can be silver paste, for example.

In one embodiment, the passivation layer covers the surface of the central region of the resistor and extends to two opposite edges of the resistor, such that it leaves uncovered the two remaining opposite sides of the resistor, wherein the two uncovered portions serve as two electrode zones. In another embodiment, two electrodes can further be separately formed on the surfaces of the two electrode zones of the resistor, the electrodes being for soldering to, for example, a circuit board that needs to measure electric potential difference, wherein, preferably, the electrodes are formed on the surfaces of the electrode zones by means of rolling plating.

The basic required property of the applied substrate is that it has an insulative nature. In addition, there are no specific restrictions. A ceramic substrate is applicable, for instance; and the basic required property of the resistor is that it is a sheet structure with a pre-defined resistance. For instance, it can be a sheet metal structure that has a central punched aperture, or a metal-coated sheet structure that has groove on its surface, or a metal-printed sheet structure that has groove on its surface.

In order to achieve the same objectives, in addition to the method described above, a chip resistor is further provided by the present invention, the chip resistor comprising: a substrate; a resistor; a thermic welding layer that bonds the substrate and the resistor together in a face-to-face orientation; and a passivation layer, which partially covers surface of the resistor, dividing the surface of the resistor into a covered portion and two uncovered portions with the covered portion located therebetween, wherein the two uncovered portions serve as electrode zones.

In summary, the chip resistor and method for fabricating the same of the present invention has the following main features: by applying a thermic welding layer to bond the substrate and the resistor together in face-to-face orientation, the present invention is capable of eliminating the drawback of the high cost of applying semiconductor fabrication processing as in the prior art, and, consequently, achieves the objectives of a simple fabrication process, increased fabrication process yield, and decreased production costs. In the invention, the surface of the resistor is divided to directly form the two electrode zones by the application of the passivation layer, wherein the two electrode zones providing a means for either direct soldering application or directly forming electrodes that are advantageous for soldering, thereby eliminating unnecessary current transmission impedance as in the prior art, as well as effectively and stably reducing the temperature coefficient of resistance.

### BRIEF DESCRIPTION OF DRAWINGS

The present invention can be more fully understood by reading the following detailed description of the preferred embodiments, with reference made to the accompanying drawings, wherein:

FIGS. 1A through 1F are flow chart diagrams of the first embodiment of the fabrication method for a chip resistor according to the present invention;

FIGS. 2A through 2F are flow chart diagrams of the second embodiment of fabrication method for a chip resistor according to the present invention; and

FIG. 3 is a diagram illustrating the heat conductance in one application state of the chip resistor of the present invention.

### DETAILED DESCRIPTION OF PREFERRED EMBODIMENTS

The following illustrative embodiments are provided to illustrate the disclosure of the present invention, these and other advantages and effects can be readily understood by those in the art after reading the disclosure of this specification. The present invention can also be performed or applied by other differing embodiments. The details of the specification may be changed on the basis of different points and applications, and numerous modifications and variations can be devised without departing from the spirit of the present invention.

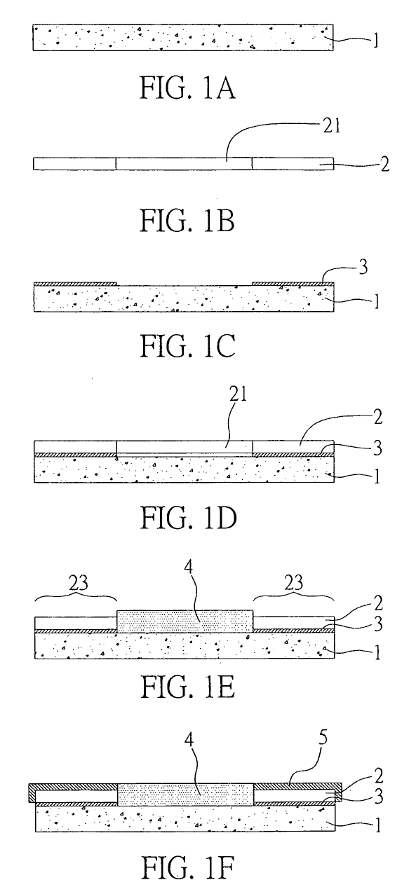

FIGS. 1A through 1F are flow chart diagrams of the first embodiment of the fabrication method of a chip resistor according to the present invention. As shown in the FIGS., the fabrication method for a chip resistor provided by the present invention is detailed in—but is not restricted to—the following descriptions.

As shown in FIGS. 1A and 1B, first, a substrate 1 and a resistor 2 are provided. The substrate 1 is, for example, a ceramic substrate that is mainly made of aluminate oxide; however, the basic required property of the substrate is its insulation property, and, other than that, there are no specific restrictions. The resistor 2 is, for example, a sheet metal structure that has a central punched aperture 21, wherein the sheet metal can be composed of a metal alloy of copper, manganese, and nickel or tin, but is not limited to these. The punched aperture 21 can be in the shape of a circle or rectangle or any other shape, as long as the area is easily calculable for converting to resistance, and it can be pre-formed by means of stamping. Naturally, the basic required property of said resistor 2 is that its resistance is pre-defined, for example, it can be a metal-coated sheet that has groove on its surface, or a metal-printed sheet that has a groove on its surface, but the design is not limited to these stated configurations.

As shown in FIGS. 1C and 1D, next, the substrate 1 and the resistor 2 are bonded together in face-to-face orientation via a thermic welding layer 3. The thermic welding layer 3 can be at least two alternate solder bumps, wherein the alternate solder bumps provide a means for further adjusting the resistance of the resistor 2 via their related positions and width. Note that there are no specified restrictions on the sequence of forming the thermic welding layer 3. In the present embodiment, a solder material is pre-coated on the top surface of the substrate 1, and then the resistor 2 is positioned on the substrate, and, after being subjected to a thermic welding process, the solder material transforms into the thermic welding layer 3 of, for instance, solder bumps that bond the substrate and the resistor together, wherein the solder material is, for example, a silver paste.

Certainly, the aforesaid thermic welding layer 3 is not limited to the application of two or more alternate solder bumps; any bonding material, which is applicable to the thermic welding process and also having good thermo-conductivity, is applicable. For example, an entire layer of silver paste can be printed on the substrate 1, and then the substrate 1 and the resistor 2 can be bonded and fixed together via a baking-welding process and drying process. The said entire layer of silver paste is functionally equivalent to the aforesaid thermic welding layer 3 of two solder bumps, but not limited to the two solder bumps as illustrated in the present embodiment. In addition, the stated baking and drying processes for solidifying are equal to a reflow process, wherein the solder material can be baked at 250, and then let dry naturally at room temperature, but the method is not restricted as stated herein either; any means that is capable of baking and drying and solidifying is suitable with the said thermic welding process according to the present invention.

As shown in FIG. 1E, next, a passivation layer 4 is applied to partially cover the exposed surface of the resistor 2, such that it divides the surface of the resistor 2 into a central covered region and two opposed uncovered regions, wherein the two uncovered regions are provided to serve as two electrode zones 23. With that step, a basic chip resistor is complete. The basic required property of the said passivation layer 4 is that it provides insulation, and, in the present embodiment, an insulating material, such as epoxy resin or others, is applied to cover the central region of the resistor 2, including the top and lateral surfaces, by means of coating. As a consequence, the two electrode zones 23 on two sides of the resistor 2 are oppositely formed, divided by the central region. In one practical application, the two electrode zones 23 formed by dividing the resistor 2 are capable of being directly soldered to an external device, for instance, directly soldered to preset circuits of a circuit board.

As shown in FIG. 1F, in order to provide convenience in soldering in subsequent practical application, an electrode 5 can further be separately formed on each of the two electrode zones 23 of the resistor 2, thus providing a means for soldering to, for instance, a circuit board that needs to measure electric potential different. In a preferred embodiment, the electrodes are formed on the electrode zones by means of rolling plating, but formation is not limited to this method; any means that is capable of forming electrodes 5 on the surfaces of the electrode zones 23 is applicable, the basic condition being that no medium is required for connecting between the electrode 5 and the electrode zone 23. For example, neither electroplating nor thermo-compression bonding needs to use a medium; therefore, both are applicable means. Also, in that the electrodes are for providing a convenient means for soldering externally, the electrodes 5 are preferably made of a metal alloy containing tin, for instance, a metal alloy of copper and nickel and tin.

It should be noted herein that all the illustrative diagrams of this embodiment are based on a fabrication method for a single chip resistor, but such a single fabrication method is not restrictive of the technological ideas of the present invention. For example, to batch process the chip resistors, any commonly used batch production method can be used to, for instance, integrate a plurality of the aforesaid ceramic substrates 1 into the configuration of a matrix pattern. Then, a plurality of the aforesaid resistors 2 can be integrated into the configuration of a matrix pattern, and, after a plurality of chip resistors are synchronously completed in subsequent processes, a cutting process can be performed to singulate the chip resistors. Various fabrication steps based on the technological ideas of the present invention should be construed to fall within the scope of the present invention; and since batch production and cutting processes can be clearly understood by those in the art, there is no need to further describe and illustrate such techniques herein.

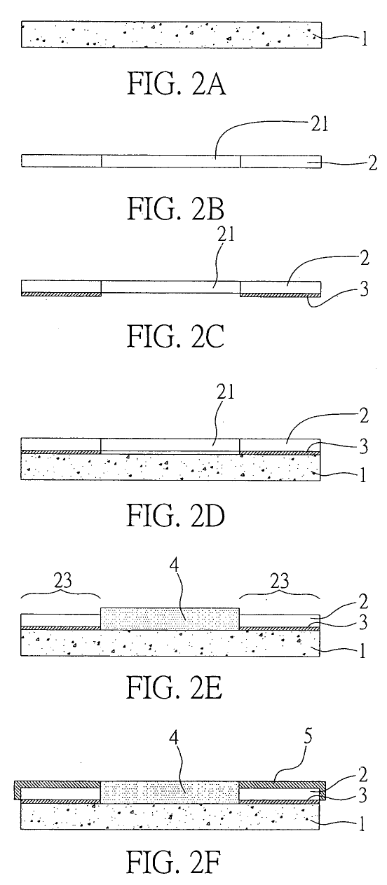

FIGS. 2A through 2F are flow chart diagrams of the second embodiment of the fabrication method for a chip resistor of the present invention, wherein the disclosed fabrication method for a chip resistor comprises steps mostly similar to that of the previously disclosed first embodiment. There is no change in the fabricated structure of the chip resistor, and, in order to simplify the illustrative description of the present embodiment, similar or identical elements will adopt the same labels, and only the differences are described in detail herein.

As shown in FIGS. 2A and 2B, first, a substrate 1 and a resistor 2 are provided, wherein the character of both the said substrate 1 and the said resistor 2 are the same as those of the first embodiment.

As shown in FIGS. 2C and 2D, next, the substrate 1 and the resistor 2 are bonded together in face-to-face orientation via a thermic welding layer 3. The thermic welding layer 3 can be either at least two alternate solder bumps or an entire layer of solder material as aforementioned. There are no specific restrictions on the sequence of forming the thermic welding layer 3. In the present embodiment, the thermic welding layer 3 consists of two solder bumps, wherein, a solder material is pre-coated on the top surface of the resistor 2, and then the resistor 2 is positioned on the substrate 1, and, after being subjected to a thermic welding process, the solder material transforms into the thermic welding layer 3 of solder bumps that bond the substrate 1 and the resistor 2 together, wherein the said solder material is, for example, a silver paste. The properties of the thermic welding layer 3 are the same as that of the first embodiment; therefore, the descriptions are not repeated herein.

As shown in FIGS. 2E and 2F, the subsequent step of forming a passivation layer 4, and, according to practical demands, the step of separately forming a electrode 5 on the surface of each of the two electrode zones 23, as well as the properties and variations of the passivation layer 4 and electrode 5 are all the same as those of the first embodiment; therefore, the descriptions are not repeated herein.

In addition, as shown in FIGS. 1E and 2E, the present invention further provides a chip resistor, which comprises: a substrate 1; a resistor 2; a thermic welding layer 3 that bonds the substrate 1 and the resistor 2 together in face-to-face orientation; and a passivation layer 4 that partially covers the resistor 2, such that the passivation layer 4 divides the top surface of the resistor 2 into a central covered region and two opposed uncovered regions, wherein the two uncovered regions are provided to serve as electrode zones 23.

The properties and structural variations of said substrate 1, said resistor 2, said thermic welding layer 3, and said passivation layer 4 are all the same as those in the previously disclosed fabrication methods; therefore, the descriptions are not repeated herein. In addition, the chip resistor of the present invention, as shown in FIG. 1F or 2F, can further comprise electrodes 5, which are separately formed on the exposed surfaces of the two electrode zones 23.

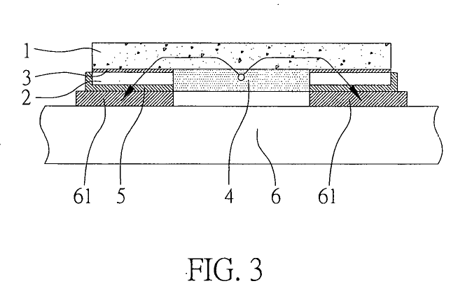

FIG. 3 is a diagram illustrating heat conduction in one application state of the chip resistor provided by the present invention while being applied to an external device, wherein the orientation of the figure is upside down with respect to the earlier figures. As shown in the figure, the electrodes 5 on the surfaces of the two electrode zones of the chip resistor are capable of being soldered to corresponding circuit contacts 61 of a circuit of an external device 6, for example, a circuit board. In accordance with the structural design of the aforesaid chip resistor, the electrodes 5 are directly connected to the resistor 2; therefore, when the resistor 2 generates heat while operating, a thermo-conductive path exists as indicated by the direction arrows in the figure. The passivation layer 4 provides an obstructive purpose, and, consequently provides the thermo-conductive path towards the substrate 1 to have better thermo-conductivity. The path then continues through the substrate 1 to the circuit contacts 61 via the electrodes 5 of the two terminals of the resistor 2. Therefore, heat can be dissipated via the substrate 1, and, at the same time, be directly conducted into the printed circuit of the external device 6 via the circuit contacts, thereby preventing the heat from directly being dissipated downwards (in the figure) to cause burning of the external device 6, for instance, a circuit board. Consequently, the design avoids undesirable variations of the temperature coefficient of resistance caused by a rising or elevated temperature of the electrodes 5 and the resistor 2, making the design applicable to products of extremely low resistance.

In summary, the chip resistor and method for fabricating the same provided by the present invention apply a thermic welding layer to bond a substrate and a resistor together in face-to-face orientation, thereby eliminating the drawback of the high cost of applying semiconductor fabrication processing as in prior art, and consequently achieving the objectives of a simple fabrication process, increased fabrication process yield, and decreased cost. In addition, the regions of the resistor not covered by the passivation layer serve as two electrode zones, which can be utilized as bases for the formation of electrodes, or can be used as electrodes themselves in direct soldering applications, thereby eliminating unnecessary current transmission impedance as in prior art, and also efficiently and stably reducing the temperature coefficient of resistance. Therefore, the chip resistor and the method for fabrication the same provided by the present invention have overcome the drawbacks of the prior art, and conform to the patent application requirements of industrial utility, novelty, and advancement.

The foregoing descriptions of the detailed embodiments are only illustrated to disclose the features and functions of the present invention and are not intended to be restrictive of the scope of the present invention. It should be understood to those in the art that all modifications and variations made according to the spirit and principles in the disclosure of the present invention should be considered to fall within the scope of the appended claims.

1. A fabrication method of a chip resistor, comprising:
providing a substrate and a resistor;
bonding the substrate and the resistor together in face-to-face orientation via a thermic welding layer; and
partially covering the resistor with a passivation layer, such that the passivation layer divides the surface of the resistor into a covered region and two opposed uncovered regions with the covered region located therebetween, wherein the two uncovered regions serve as electrode zones.

2. The fabrication method of the chip resistor of claim 1, wherein the thermic welding layer is at least two alternate solder bumps.

3. The fabrication method of the chip resistor of claim 2, wherein a solder material is pre-coated on the surface of the substrate, and then the resistor is adhered on to the substrate; and, after being subjected to a thermic welding process, the solder material transforms to the solder bumps that bond the substrate and the resistor together.

4. The fabrication method of the chip resistor of claim 2, wherein a solder material is pre-coated on the surface of the resistor, and then the resistor is adhered on to the substrate; and, after being subjected to a thermic welding process, the solder material transforms to the solder bumps that bond the substrate and the resistor together.

5. The fabrication method of the chip resistor of claim 3, wherein the solder material is a silver paste.

6. The fabrication method of the chip resistor of claim 3, wherein the solder material bonds and fixes the substrate and the sheet metal together via a baking-welding process and a drying process.

7. The fabrication method of the chip resistor of claim 1, wherein the passivation layer covers the surface of the central region of the resistor and extends to two opposite sides of the resistor, thus dividing the resistor into a central covered region and two uncovered regions with the central covered region located therebetween, wherein the two uncovered regions serve as electrode zones.

8. The fabrication method of the chip resistor of claim 7, further comprising: separately forming two electrodes on the two electrode zones of the resistor.

9. The fabrication method of the chip resistor of claim 8, wherein the electrodes are formed on the surfaces of the electrode zones by means of rolling plating.

10. The fabrication method of the chip resistor of claim 1, wherein the substrate is a ceramic substrate.

11. The fabrication method of the chip resistor of claim 10, wherein the ceramic substrate is made of aluminate oxide.

12. The fabrication method of the chip resistor of claim 1, wherein the resistor is a sheet metal structure that has a central aperture.

13. The fabrication method of the chip resistor of claim 1, wherein the resistor is a metal-coated sheet structure that has groove on its surface.

14. The fabrication method of the chip resistor of claim 11, wherein the resistor is a metal-printed sheet structure that has groove on its surface.

15. A chip resistor, comprising:
a substrate;
a resistor;
a thermic welding layer, which bonds the substrate and the resistor together in face-to-face orientation; and
a passivation layer, which partially covers the surface of the resistor, such that the passivation layer divides surface of the resistor into a covered portion and two opposed uncovered portions with the covered portion located therebetween, wherein the two uncovered portions serve as electrode zones.

16. The chip resistor of claim 15, wherein the thermic welding layer is at least two alternate solder bumps.

17. The chip resistor of claim 16, wherein the solder bumps are made of silver.

18. The chip resistor of claim 15, wherein the passivation layer covers the surface of a central region of the resistor and extends to the sides of the resistor, and consequently divides the resistor into a central covered region and two opposed uncovered regions with the central covered region located therebetween, wherein the two uncovered regions serve as the electrode zones.

19. The chip resistor of claim 18, further comprising two electrodes that are separately formed on the two electrode zones of the resistor.

20. The chip resistor of claim 15, wherein the substrate is a ceramic substrate. The chip resistor of claim 15, wherein the resistor is a structure selected from the group of a sheet metal structure that has central punched aperture, a metal-coated sheet structure that has groove on its surface, and a metal-printed sheet structure that has a groove on its surface.
